(19) United States
(12) Patent Application Publication
(10) Pub. No.: US 2006/0240324 A1
(43) Pub. Date: Oct. 26, 2006

(54) Multifunctional doped conducting polymer-based field effect devices

(76) Inventors: Arthur J. Epstein, Bexley, OH (US); Oliver B. Waldmann, Bern (CH); June Hyoung Park, Columbus, OH (US); Nan-Rong Chiou, Columbus, OH (US); Youngmin Kim, GyeongGi-Do (KR)

Correspondence Address: FAY, SHARPE, FAGAN, MINNICH & MCKEE, LLP, 1100 SUPERIOR AVENUE, SEVENTH FLOOR, CLEVELAND, OH, 44114, US

(21) Appl. No.: 11/089,676

(22) Filed: Mar. 25, 2005

Related U.S. Application Data
(60) Provisional application No. 60/556,232, filed on Mar. 25, 2004.

(51) Int. Cl. H01M 4/60; H01M 4/58; H01L 27/12

(52) U.S. Cl. 429/212; 257/347; 429/218.1

(57) ABSTRACT

Electric field driven devices and methods of operation are provided. Each device use one or more doped conducting polymers to provide multifunctional responses to applied electric field. The device includes an electrically conductive layer operative to provide a gate contact for the device; a conducting polymer layer operative to provide source and drain contacts for the device, and an active layer; and an insulating polymer layer formed between the electrically conductive layer and the conducting polymer layer, wherein the layers in combination allow the device to be operative to perform at least two of a plurality of response functions.

This application claims priority to and the benefit of U.S. Provisional Application No. 60/556,232 filed Mar. 25, 2004, which application is incorporated herein by reference in its entirety.

This development is supported by the Office of Naval Research, Grant No. N00014-01-1-0427.

### BACKGROUND

This invention relates to an electric field driven device prepared using one or more doped conducting polymers such as poly(3,4-ethylenedioxythiophene) (PEDOT), polypyrrole (PPy), and polyaniline (PAni), and their co-polymers and blends, with inorganic dopants such as Cl and ClO₄ and/or organic dopants such as methane sulfonic acid and camphorsulphonic acid, and their mixtures, to provide multifunctional responses to an applied electric field.

The present exemplary embodiments relate to modulation of reflectivity/emissivity and conductivity, amplifiers, current sources, nonvolatile memory and supercapaciter applications. However, it is to be appreciated that the present exemplary embodiments are also amenable to other like applications.

The field-effect transistor (FET) is the most common transistor today. The FET operates by controlling the current through a semiconductor material using an electric field. In recent years, doped and undoped semiconductor polymers have been prepared to provide active elements in electronic field effect devices. “Electric-Field Induced Ion-Leveraged Metal-Insulator Transition in Conducting Polymer Transistors”, by the current inventor, Arthur J. Epstein et al., discusses undoped and doped semi-conductor polymers and their application to FETs, and is hereby totally incorporated by reference.

Conventionally, polymer FETs are used as inverting amplifiers, current sources, etc.; the FET configuration provides one function. This disclosure presents a polymer FET device which is capable of multiple functions.

### BRIEF DESCRIPTION

In accordance with one aspect of the present exemplary embodiment, a field effect device is provided that comprises an electrically conductive layer operative to provide a gate contact for the device; a conducting polymer layer operative to provide source and drain contacts for the device, and an active layer; and an insulating polymer layer formed between the electrically conductive layer and the conducting polymer layer, wherein the layers in combination allow the device to be operative to perform at least two of a plurality of response functions. The plurality of response functions comprising: varying reflectance and emissivity of electromagnetic radiation over a surface area by applying a voltage between the electrically conductive layer and the conducting polymer layer; modulating electrical conductivity between the source contact and the drain contact by applying a voltage between the conducting polymer layer and the electrically conductive layer; amplifying low frequency electrical signals; acting as a current source; storing information in a non-volatile, re-writable form; storing electrical charge and energy as a supercapacitor between the conducting polymer layer and the electrically conductive layer, separated by the insulating polymer layer; and sensing the presence of organic, inorganic or biologic species.

In accordance with another aspect of the present exemplary embodiment, a method of operating a field effect device is provided, comprising an electrically conductive layer operative to provide a gate contact for the device, the electrically conductive layer operative to provide a reflective surface; a conducting polymer layer operative to provide source and drain contacts for the device, and an active layer; and an insulating polymer layer formed between the electrically conductive layer and the conducting polymer layer, the method comprising the steps of: combining the layers to allow the device to be operative to perform at least two of a plurality of response functions. The plurality of response functions comprising: varying reflectance and emissivity of electromagnetic radiation over a surface area by applying a voltage between the electrically conductive layer and the conducting polymer layer; modulating electrical conductivity between the source contact and the drain contact by applying a voltage between the conducting polymer layer and the electrically conductive layer; amplifying low frequency electrical signals; acting as a current source; storing information in a non-volatile, re-writable form; storing electrical charge and energy as a supercapacitor between the conducting polymer layer and the electrically conductive layer, separated by the insulating polymer layer; and sensing the presence of organic, inorganic or biologic species.

### BRIEF DESCRIPTION OF THE DRAWINGS

FIG. 1 is a schematic of a multi-function doped polymer field effect modulated device according to one embodiment of the disclosure;

FIG. 2A is a conducting polymer representation;

FIG. 2B is an insulating polymer layer material;

FIG. 3A is a conducting polymer representation;

FIG. 3B is a conducting polymer representation;

FIG. 3C is a conducting polymer representation;

FIG. 4A is a 50% sulfonated polyanilines representation;

FIG. 4B is a 100% sulfonated polyanilines representation;

FIG. 5A is the top schematic view of a multi-function doped polymer field effect modulated device according to one embodiment of the disclosure;

FIG. 5B is the A-A sectional view of FIG. 5A;

FIG. 6A is a graph representing the variation versus time for I_{SD}, I_{GS} and V_{G} according to a device as illustrated in FIGS. 5A and 5B;

FIG. 6B is a graph representing absolute reflectance, R, and reflectance normalized to the reflectance in the absence of an applied gate voltage (R₀), R/R₀ in the spectral range of 30 cm⁻¹ to 630 cm⁻¹, according to a device as illustrated in FIGS. 5A and 5B;

FIG. 7 is a graph representing an enlarged view of FIG. 6B;

FIG. 8A is a graph representing the reflectivity in the spectral range of 30 cm⁻¹ to 630 cm⁻¹ of a device according to FIGS. 5A and 5B for applied gate voltages of 0V and 2V;

FIG. 8B is a graph representing the conductivity of a device according to FIGS. 5A and 5B;

FIG. 9A is a graph representing the variation versus time for I_{SD}, I_{GS} and V_{G} according to a device as illustrated in FIG. 5A;

FIG. 9B and FIG. 9C are graphs representing the transmittance in the spectral range of 3500 cm⁻¹ to 28000 cm⁻¹ of a device according to FIGS. 5A and 5B for applied gate voltages of −1, 0, 1 V and −3, 0, 3 V;

FIG. 10 is a graph representing the switching speed of a device according to FIG. 1 with variation of an applied gate voltage;

FIG. 11 is a graph representing the variation of conductance of a device according to FIG. 1 with variation of an applied gate voltage, the device of FIG. 11 has smaller dimensions then that of FIG. 10 and the I_{SD} of this device changes by approximately a factor of 20000 with application of a gate voltage;

FIG. 12 is a graph representing the I_{SD} of another device according to FIG. 1 demonstrating a change of I_{SD} of this device by approximately a factor of 100000 with application of a gate voltage;

FIG. 13A is a graph representing the switch-off time of a device according to FIG. 1 demonstrating stepwise change of I_{SD} with step changes in V_{G} from −1.5 V to 2.5 V in steps of 0.5 V;

FIG. 13B is a graph representing the switch-on time to switch-off time ratio of a device according to FIG. 1 demonstrating a very rapid switch of a factor of nearly 1000 in I_{SD} for device structures with separation between source and drain contact of approximately 40 microns;

FIG. 14A is a graph illustrating drain current as a function of a drain-source voltage, as the gate voltage is varied for a device according to FIG. 1;

FIG. 14B is a graph representing the saturation current as a function of the gate-source voltage for a device according to FIG. 1;

FIG. 15A is an inverting amplifier configuration according to a device illustrated in FIG. 1;

FIG. 15B is a graph representing the amplification of the inverting amplifier according to FIG. 15A at a given frequency;

FIG. 15C is a graph representing the amplification of the inverting amplifier according to FIG. 15A, according to another given frequency;

FIG. 16A is an inverting amplifier configuration according to a device as illustrated in FIG. 1;

FIG. 16B is a graph representing the input and output voltage of a device configuration according to FIG. 16A;

FIG. 16C is another graph representing the input and output voltage of a device configuration according to FIG. 16A;

FIG. 17A is a current source configuration according to a device as illustrated in FIG. 1;

FIG. 17B is a graph representing the drain current as a function of the drain-source voltage of a device configuration according to FIG. 17A; and,

FIGS. 18A, 18B and 18C are graphical representations of the non-volatile random access memory (RAM) response of a device according to FIG. 1.

### DETAILED DESCRIPTION

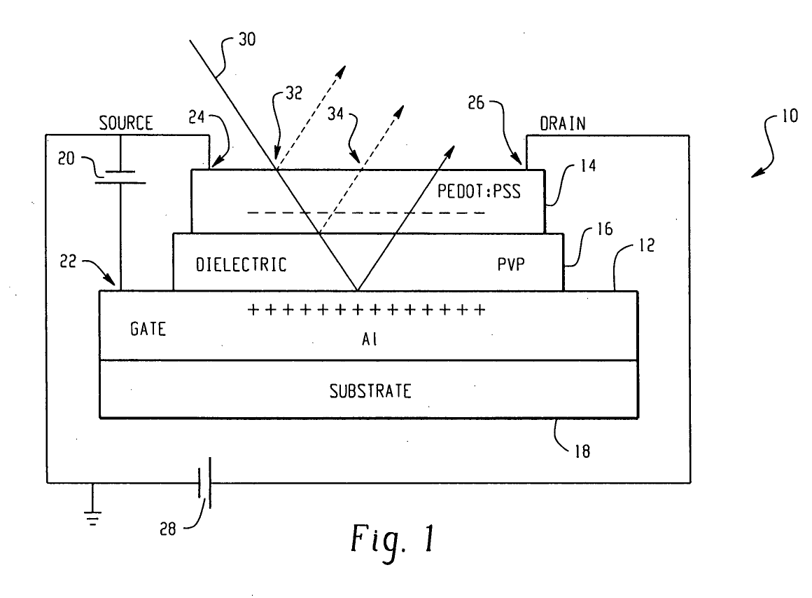

According to the present disclosure, a multi-function doped conducting polymer-based electric field effect device structure is provided, as shown schematically in FIG. 1. As illustrated, the device 10 includes an electrically conductive layer 12 (e.g., a metal layer such as an aluminum layer), a conducting polymer layer 14 (e.g., PEDOT:PSS), an insulating polymer layer 16 (e.g., a dielectric such as PVP, polyethylene oxide or other non-electrically conductive polymer) disposed between the metal layer 12 and the conducting polymer layer 14. The conducting polymer layer 14 provides the active region for the field effect device 10. Alternatively, the electrically conducting layer 12 may be replaced by another type of electrically conductive material such as an electrically conductive polymer which may be coated with a highly reflective surface such as metallic or a non-metallic reflective surface, e.g. coated Mylar. Notably, the layer 12 acts as a gate contact 22 for the device while the conducting polymer layer 14 acts as a source contact 24 and a drain contact 26 for the device 10. Also representatively shown in FIG. 1 is circuitry that is suitably implemented to connect to the gate 22, source 24 and drain 26 contacts and allow for operation of the device.

It should be understood that the device illustrated in FIG. 1 may take a variety of configurations, that which is shown being merely an example. Moreover, the device may be rigid, semi-rigid, conformable or flexible. It should be further understood that the respective layers of the device 10 may be formed of other suitable materials, some of which are identified herein. It should be still further understood that the device 10 of FIG. 1 may be fabricated using a variety of techniques. Examples of these techniques are disclosed by “Electric-Field Induced Ion-Leveraged Metal-Insulator Transition in Conducting Polymer Transistors”, referenced above.

Such techniques may depend upon the materials used and the desired configuration of the device. Still further, given the multifunctional nature of the device, it may be implemented in a variety of environments.

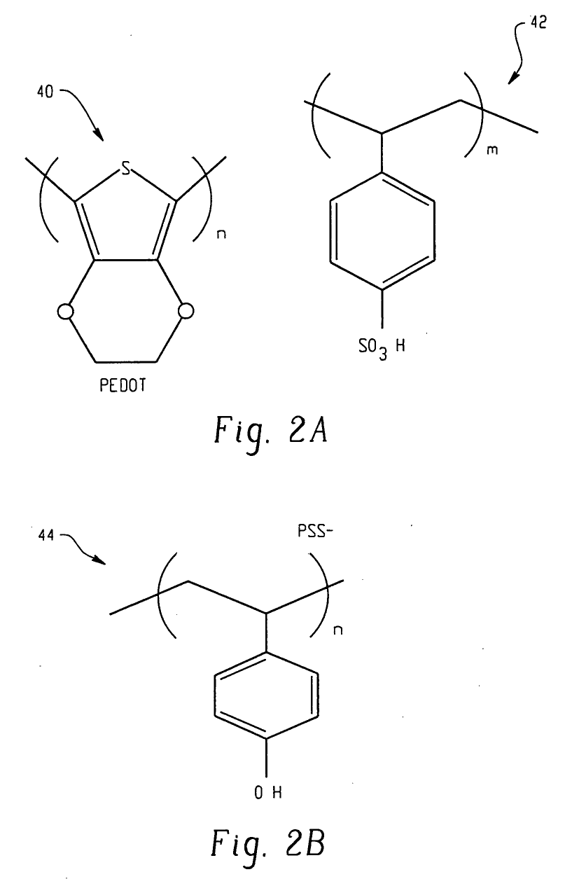

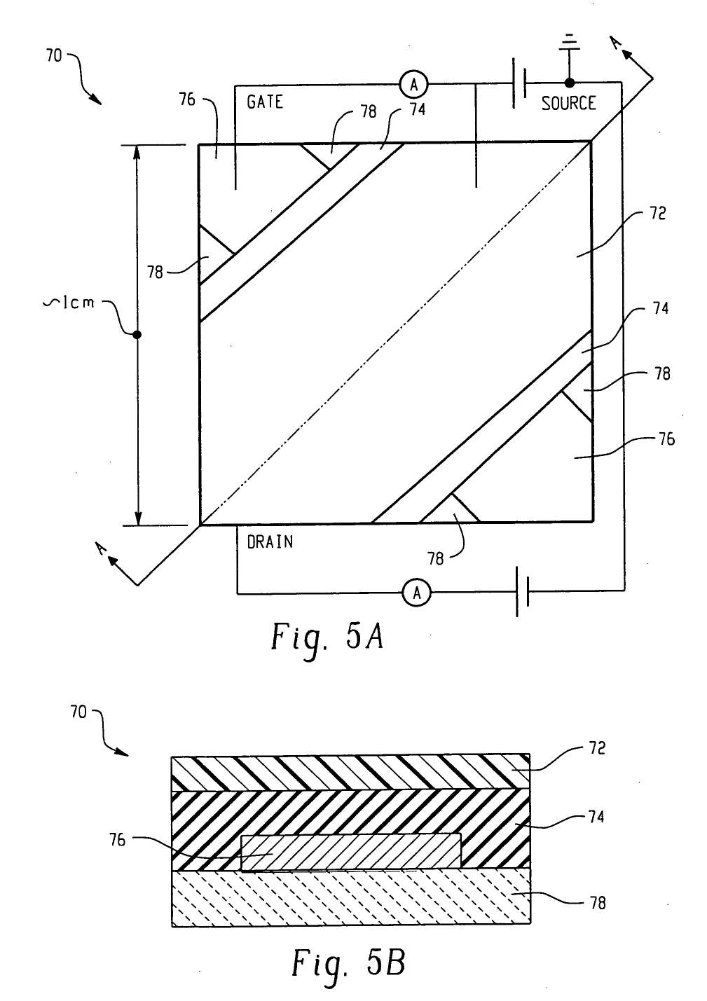

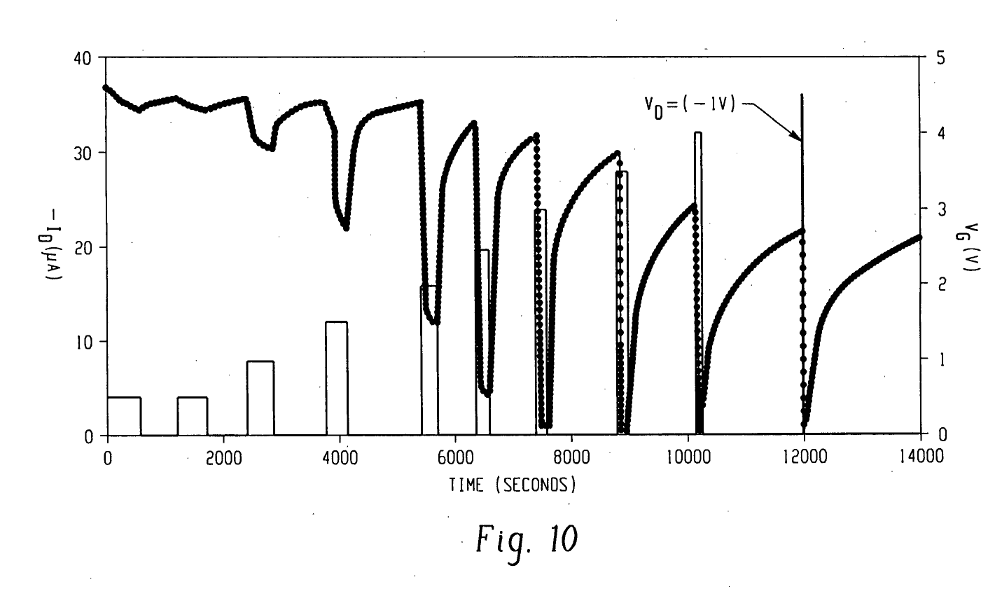

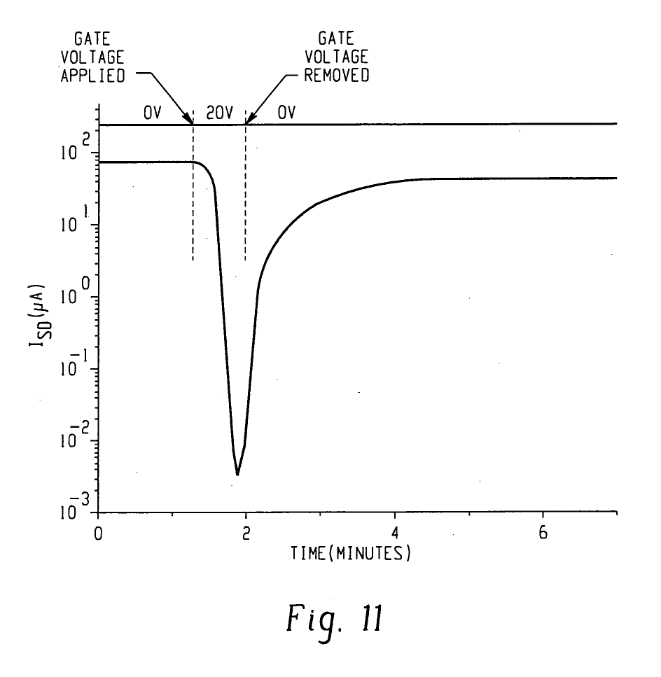

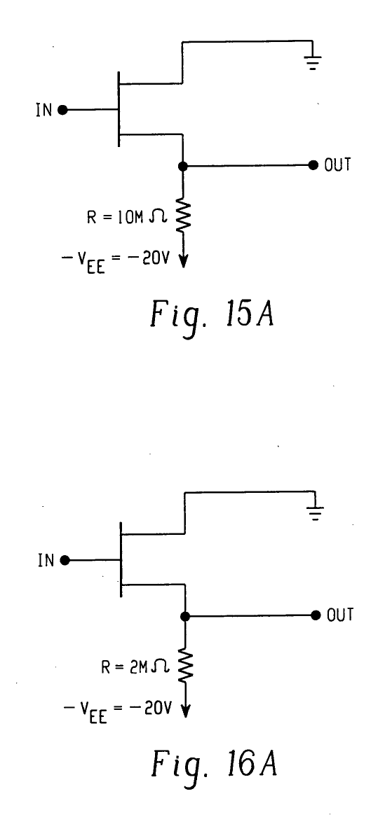

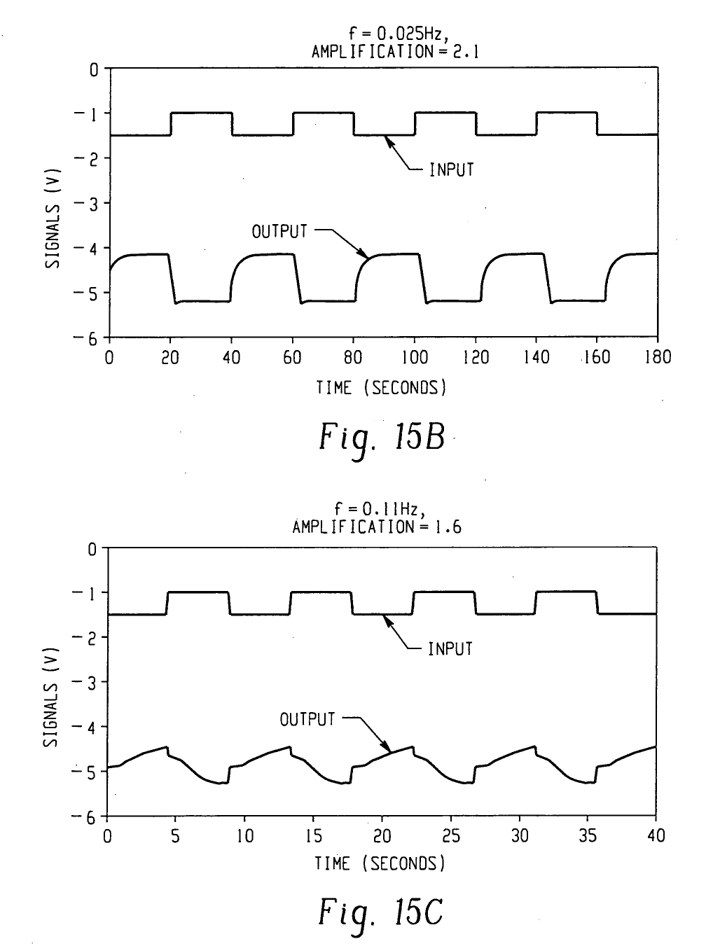

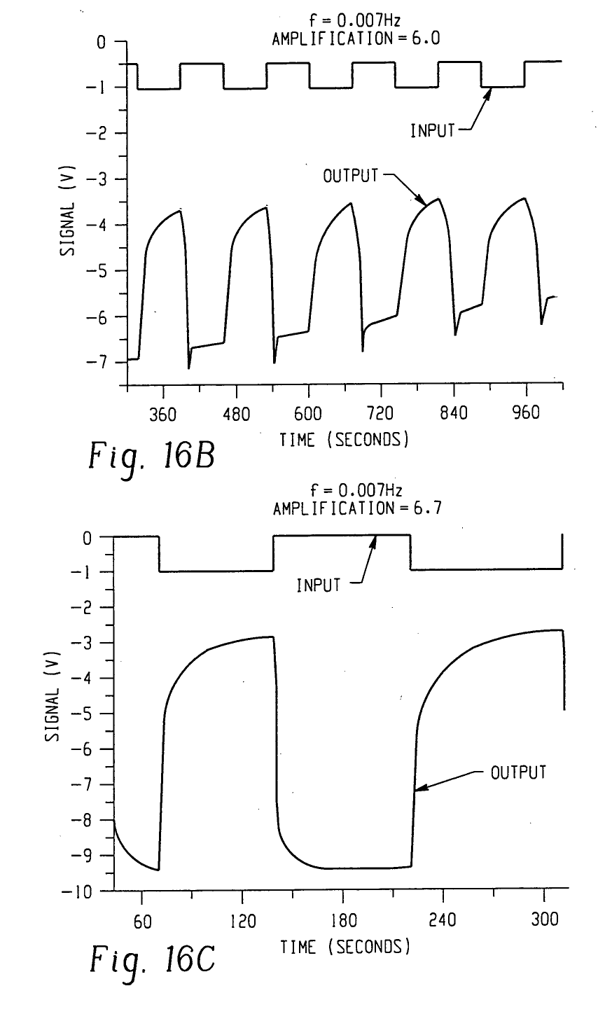

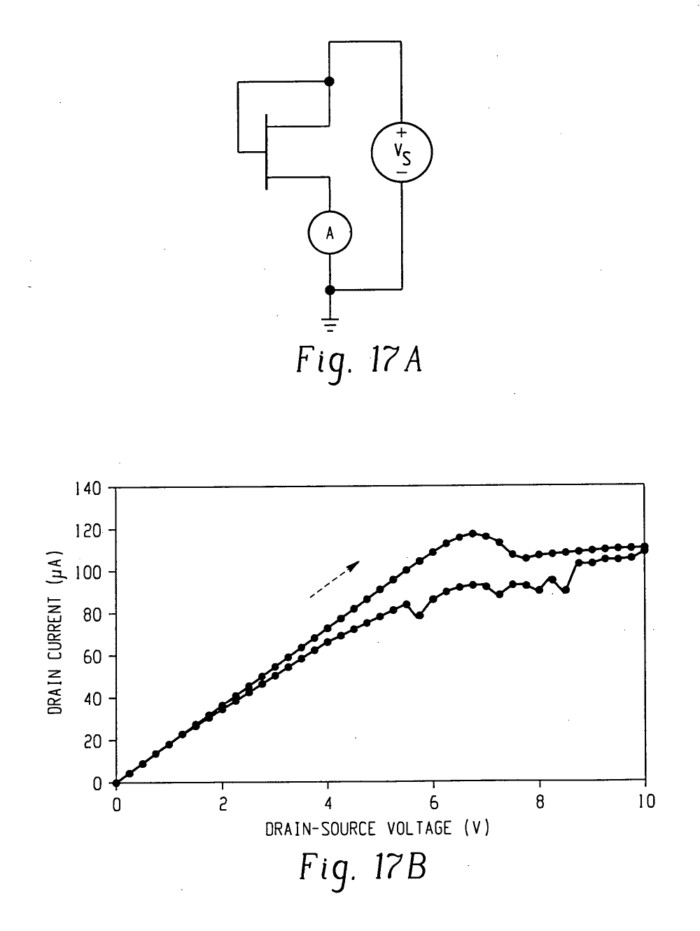

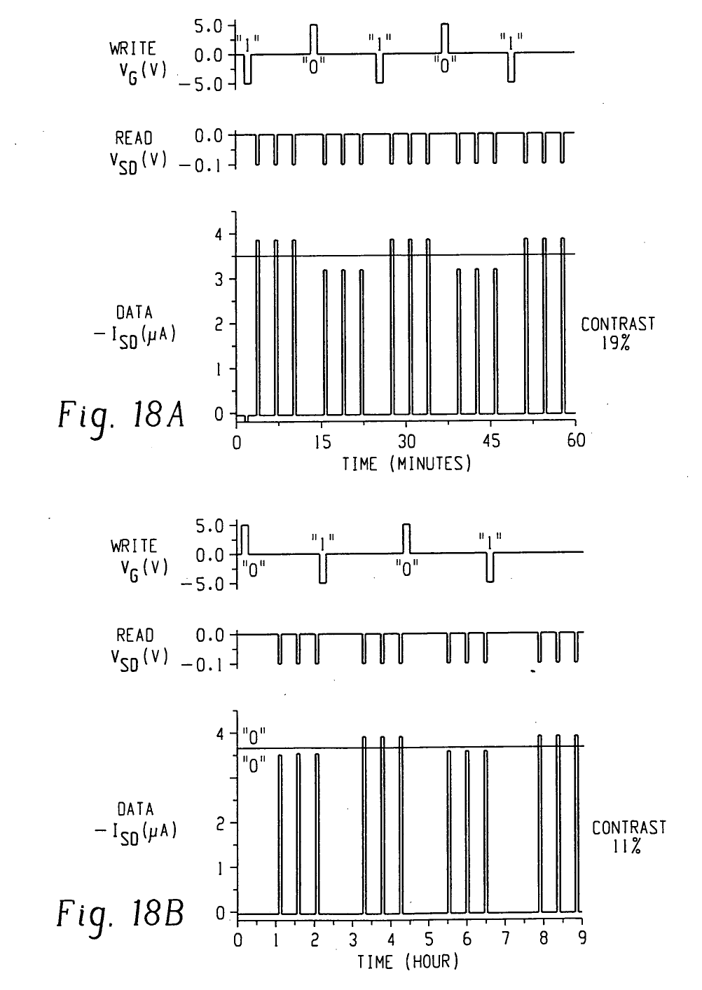

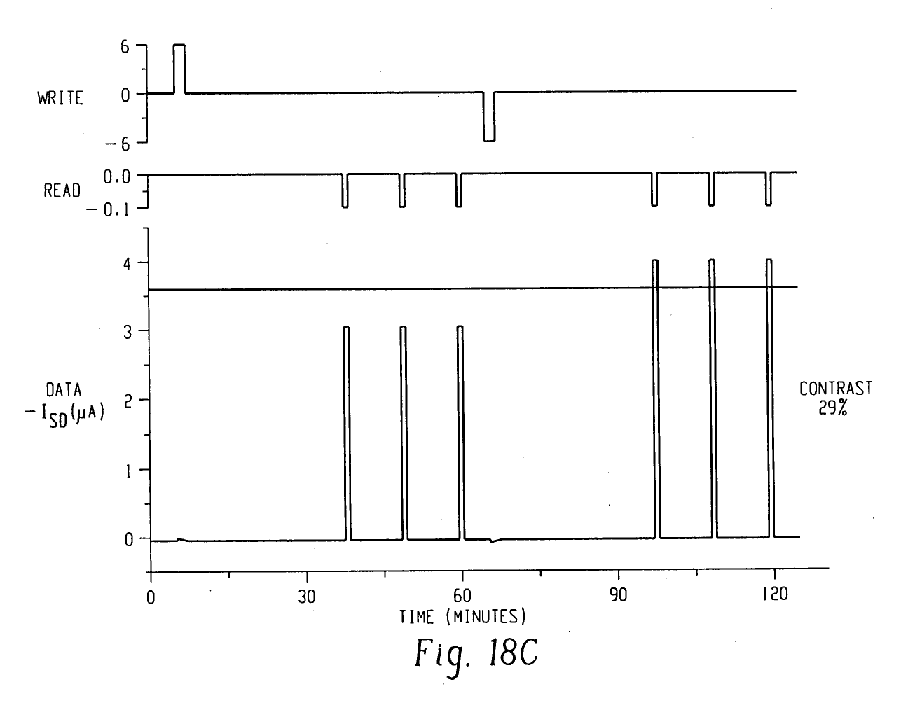

Examples of doped conducting and dielectric polymers used in the device structure are shown in FIGS. 2A-2B, 3A-3C and 4A-4B. This structure may have active areas varying from less then a square micron to more than a square centimeter, for example more than a square meter. This structure incorporates multiple response functions within the structure, including at least two of the following:
vary reflectance and emissivity of electromagnetic radiation, especially infrared, over a broad surface area by application of a small voltage between a bottom metal reflector and top conducting polymer layer (FIGS. 5A-9C);
modulate the electrical conductance between the source and drain contacts on the conducting polymer layer by application of an electric voltage between conducting polymer and metals layers (FIGS. 10-14B);
amplify low frequency electronic signals when used as a circuit element (FIGS. 15A-16C);
act as a current source (FIGS. 17A-17B);
store information in nonvolatile, rewritable form (FIGS. 18A-18C); store electric charge and energy as a supercapacitor between the top conducting polymer layer (represented here by PEDOT:PSS) and the lower metallic (gate) layer (represented by Al) separated by a polymer dielectric layer (represented by poly(vinyl phenol) (PVP)) (FIG. 1); and,
sense the presence of organic, inorganic or biologic species.

As to the method of operation, it will be understood that this is accomplished through insertion of a small number of ions into disordered portions of the conducting polymer layer, thereby interrupting the charge flow in the polymer and enabling the multifunctional response. Accordingly, the devices can be optimized to provide two or more functions at the same time.

The following figure descriptions will provide further details regarding the features discussed hereinto.

With reference to FIG. 1, illustrated is a schematic of a multi-function doped polymer field effect modulated device with voltage controlled energy/power storage, conductance, and reflectance/emissivity.

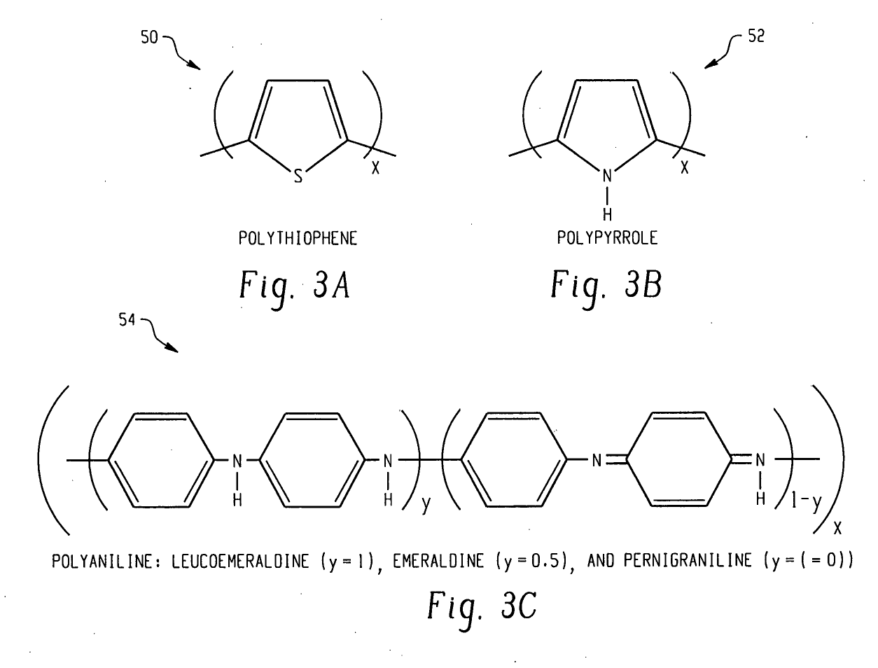

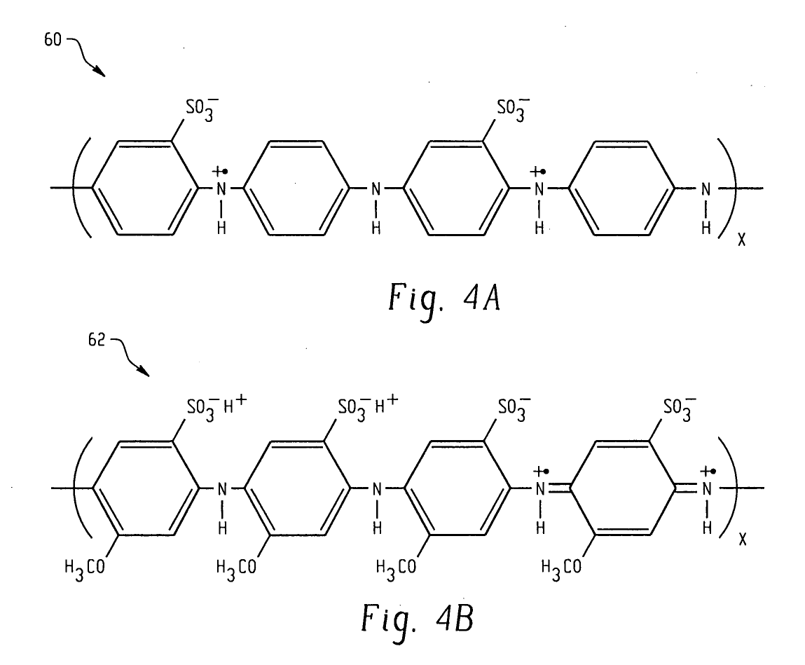

This field effect device includes a conducting polymer layer 14 as an active material. The conducting polymer layer 14 is composed of the conducting polymer PEDOT:PSS [poly(3,4-ethylene dioxythiophene)/poly(styrenesulfonic acid)], the chemical formula which is illustrated in FIG. 2A. Other typical conducting polymers which may be used are illustrated in FIGS. 3A-3C. FIG. 3A represents the backbone structure for polythiophene, FIG. 3B represents the backbone structure for polypyrrole, and FIG. 3C represents the backbone structure for polyaniline in the leucoemeraldine (y=1), emeraldine (0.35<y<0.65) and pernigraniline (y=0) forms. Each of the polymer backbones represented in FIGS. 3A-3C may be further functionalized at one through all carbon and nitrogen sites with alkyl, alkoxy, and acene and polyacene containing units as well as pyridine containing units. FIG. 4A and FIG. 4B represent 50% and 100% sulfonated polyanilines (self-doped polymers), respectively. These polymers may be further functionalized at carbon and nitrogen sites with alkyl and alkoxy groups. The degree of sulfonation may vary from 10% to 100% continuously. The conducting polymer layer 14 of the device structure in FIG. 1, in this example, is doped with Cl. The insulating layer 16 is prepared using a dielectric such as a PVP [poly(4-vinyl phenol)] as illustrated in FIG. 2B, polyethylene oxide or other non-electrically conductive polymer. The electrically conductive layer 12 is prepared using a metal, e.g. aluminum, gold, silver, or other highly reflective material such as an electrically conductive polymer coated with a reflective surface. As illustrated, the doped conducting polymer layer 14 provides source 24 and drain 26 contacts. Despite its very light level of doping as compared to conventional semiconductors such as Si used to form FETs, this polymer layer 14 responds to an applied gate voltage as a semiconductor with an active region. The reflective conductive layer 12 provides the gate contact 22 for the device 10. A voltage is applied to the gate contact 22 by a voltage source, represented as 20. The electric field caused by the gate voltage penetrates the insulating layer 16 and reaches the doped conductive polymer layer 14. The resulting small ion motion between insulating and conducting polymer layers enables a current to flow from the drain contact 26 to the source contact 24. Voltage source 28 provides the necessary energy to enable current to flow through the device 10.

Also illustrated in FIG. 1 is electromagnetic radiation 30 applied to a surface area 32 of the field effect device. The electromagnetic radiation provides an additional electrical field which penetrates the doped conducting polymer layer 14. This may result in additional ion movement within the conducting polymer layer 14 thereby providing a further modulation in conductivity between the source 24 and drain 26 contacts. In addition, the reflective surface of layer 12 provides a means to reflect the electromagnetic radiation penetrating both the conducting polymer layer 14 and insulating layer 16. The reflected radiation is transmitted through the surface 34 of the device 10. As is discussed below, the amount of reflectance can be controlled by the gate voltage of the device 10.

With reference to FIGS. 5A and 5B, illustrated are a top view and a sectional view, respectively, of a multi-function doped polymer field effect modulated device 70. This device 70 includes a doped conducting polymer 72, an insulating layer 74, a reflective conducting layer 76 and a substrate 78, e.g. glass. The arrangement of the layers is illustrated in FIGS. 5A and 5B.

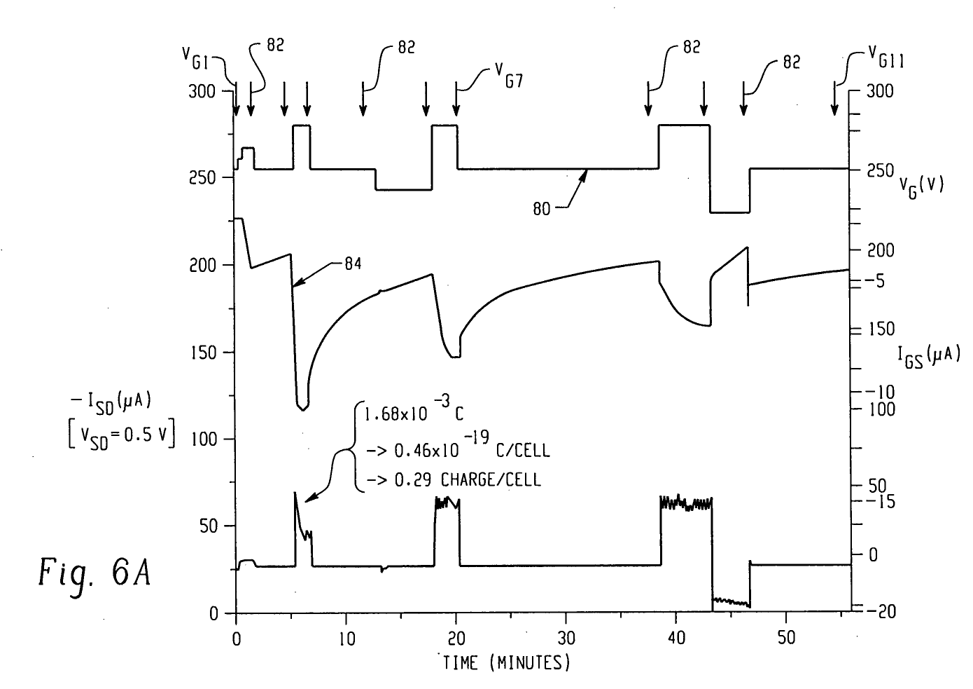

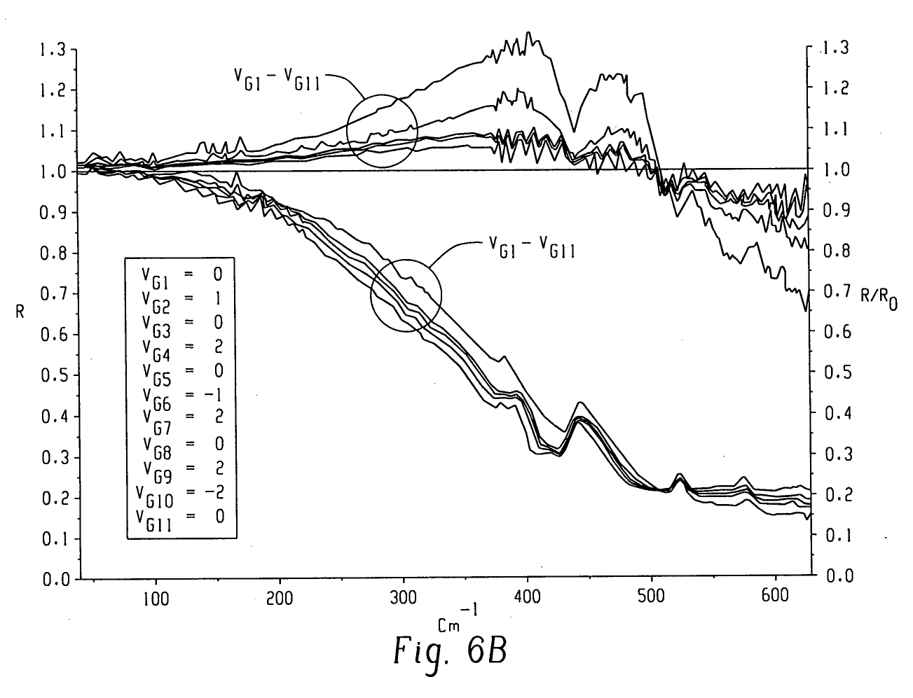

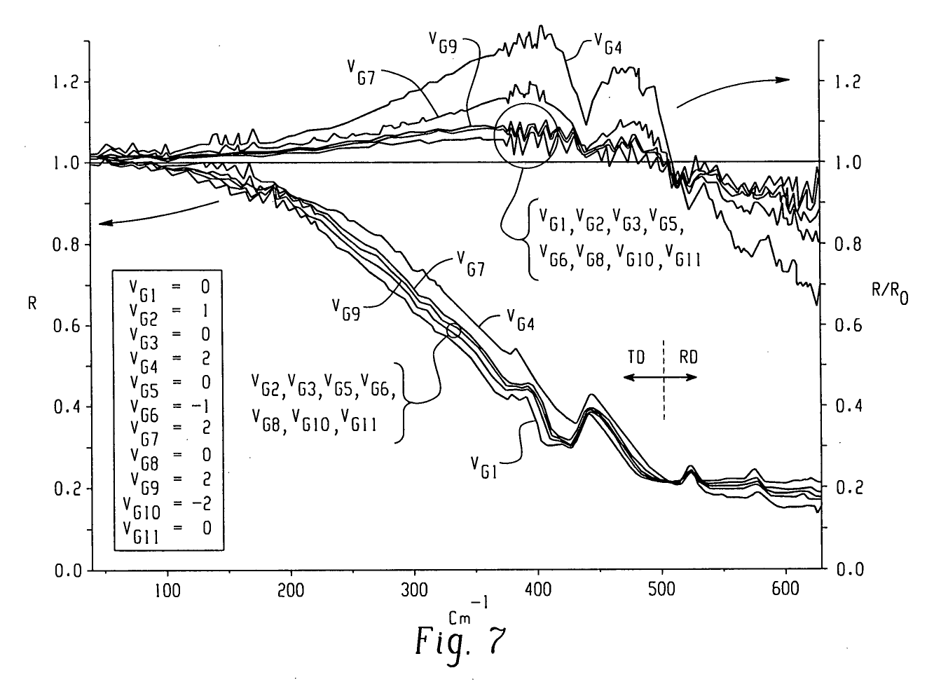

With reference to FIGS. 6A and 6B, illustrated are graphs representing the performance characteristics of a device according to FIGS. 5A and 5B. The device 70 composition is Glass/Al(0.3 μ)/PVP(0.6 μ)/Baytron (0.7 μ) with an active area of 52 mm². FIG. 6A illustrates the time varying gate voltage V_{G} 80 applied to the device 70 between the gate 76 and conducting polymer 72. The value of the gate voltage is varied between 0, +2 V, and −2 V at times marked by arrows 82. As the amplitude of V_{G} changes, as a function of time, the source to drain current is modulated 84, as well as the gate to source current. As illustrated by FIG. 6B, the reflectivity R and the change in reflectivity R/R₀ of the device 70 changes as a function of V_{G}. R₀ represents the reflectivity of the device 70 with V_{G}=0, and R represents the reflectivity of the device 70 with V_{G} equal to a value between −2V to +2V. The reflectivity ratio R/R₀ represents the change in reflectivity of the device 70 as V_{G} is applied. As is illustrated in FIG. 6B, the reflectivity ratio R/R₀, with a constant V_{G}, also varies as a function of the radiation frequency (wavelength). FIG. 7 is an enlarged view of FIG. 6B and better illustrates R/R₀ as a function of V_{G}. These graphs demonstrate reversible modulation of reflectance by gate bias. In addition, as large as a ˜30% R modulation for ˜40% I_{SD} modulation can be achieved. As illustrated in FIG. 6B, a transmission dominant (TD) region and a reflection dominant (RD) region are obtained. The results illustrated by FIG. 7 show a reversible change in IR reflectance for the PEDOT:PSS field effect structure with application of a gate voltage up to 2 volts.

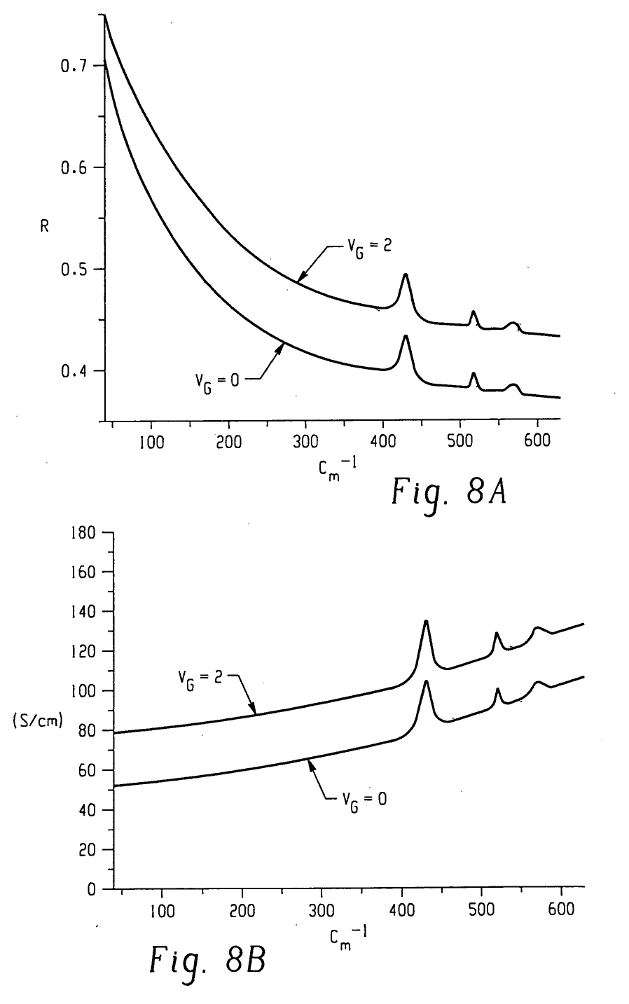

With reference to FIGS. 8A and 8B, illustrated are graphs representing reflectivity and conductivity, respectively, as a function of the radiation frequency of an external electromagnetic wave received by a device 70 as illustrated in FIGS. 5A and 5B. As can be seen in FIG. 8A, the reflectivity of device 70 increases as V_{G} is increased, especially the infrared. In addition, and simultaneously, the conductivity of device 70, as measured between the drain and source increases as the V_{G} is increased. By simultaneously achieving the function of reflection/emission control and conductivity control, the doped conducting polymer field effect device of FIGS. 5A and 5B provides multi-functionality.

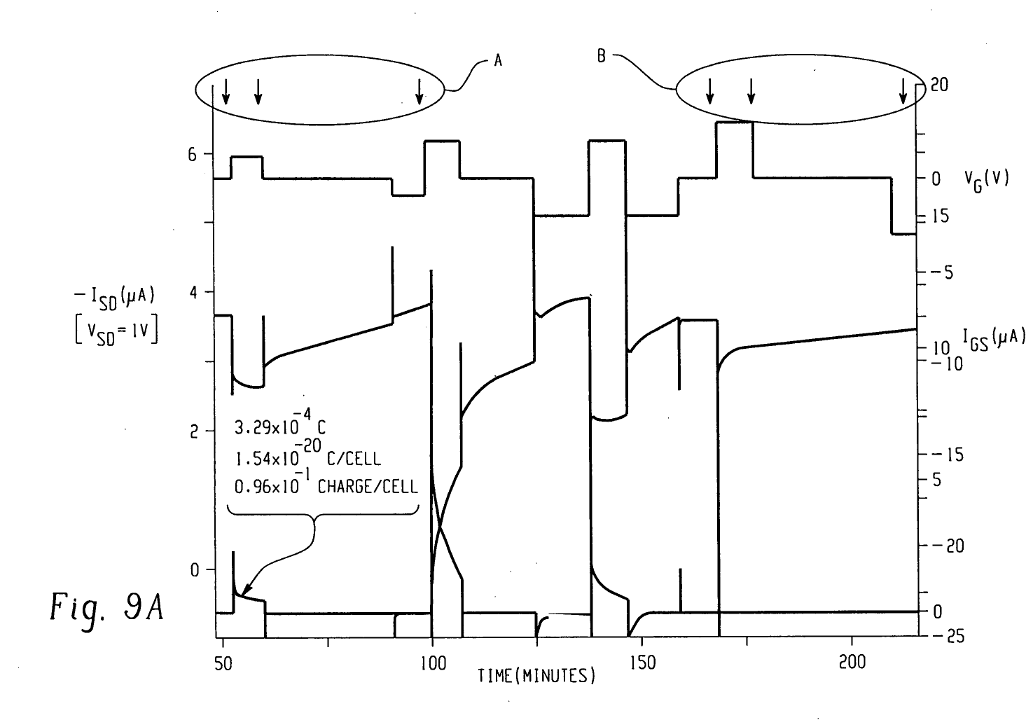

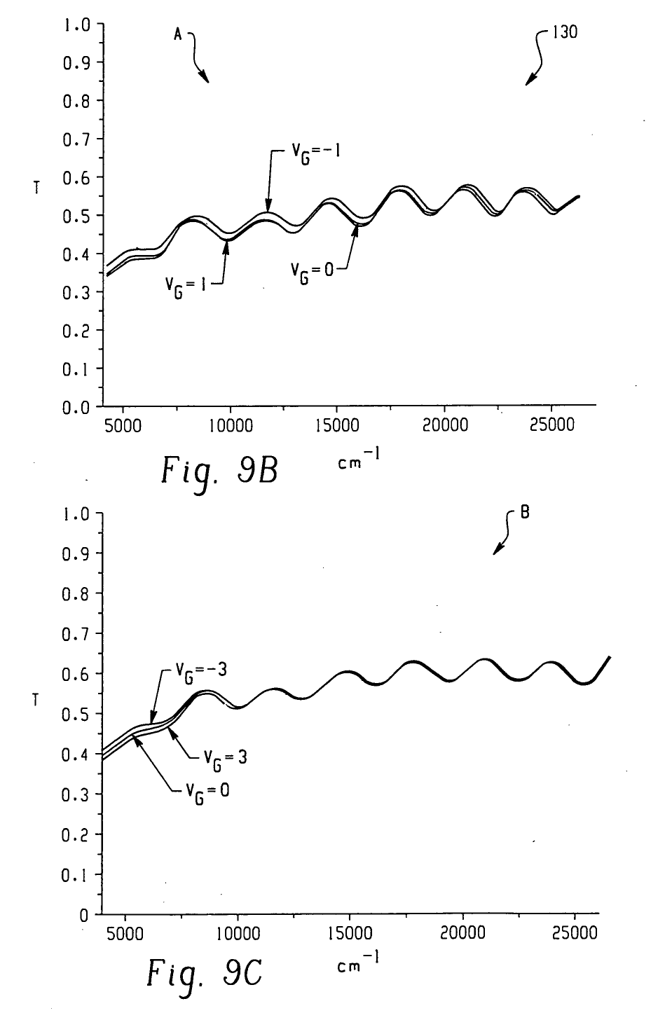

With reference to FIGS. 9A-9C, illustrated are graphs representing the transmission characteristics in the visible and near infrared and near ultraviolet spectral region of 3500 cm⁻¹ through 28000 cm⁻¹ of a device according to FIGS. 5A and 5B. The device is composed of Glass/Al(6 nm)/PVP(0.8 μ)/BP(0.25 μ) and includes an active area of 85.2 mm². These graphs demonstrate an approximate 3% transmittance change for an approximate 45% I_{SD} change, for radiation ranges in the ultraviolet and visible spectrum. FIG. 9B illustrates section (A) of FIG. 9A and FIG. 9C illustrates section (B) of FIG. 9A.

With reference to FIG. 10, illustrated is a graph which represents the switching speed of a device according to FIG. 1. The relatively slow switching speed implies that ion motion is important.

With reference to FIG. 11, illustrated is a graph of the conductance of a device according to FIG. 1. The active polymer is PEDOT:PSS. This example shows a decrease of conductance by a factor of 10⁵ after applying a gate voltage of 20V. In addition, the recovery of the conductance is illustrated after the gate voltage is removed.

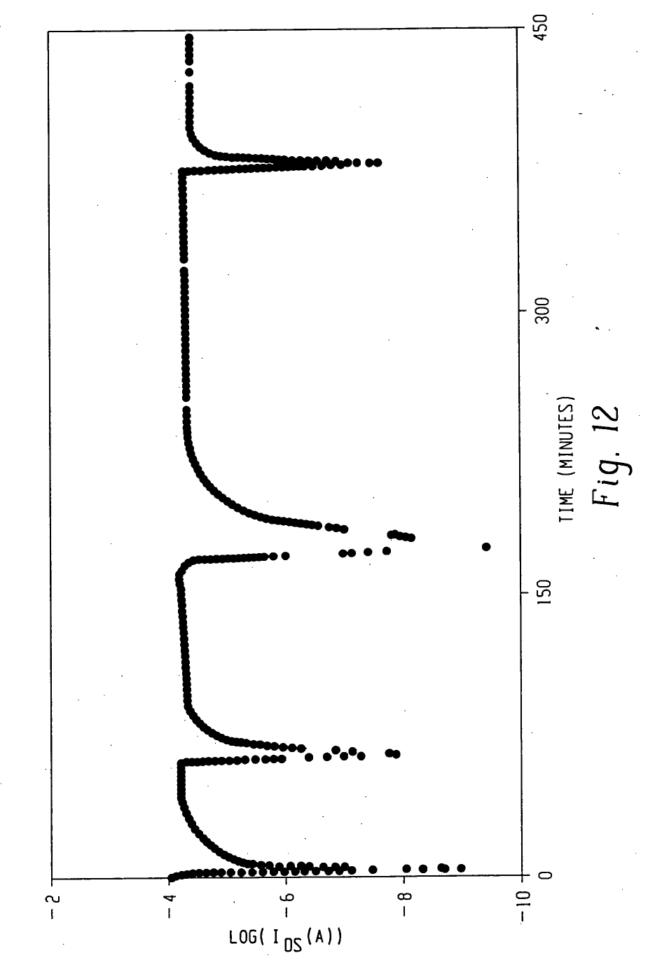

With reference to FIG. 12, illustrated is a graph of I_{DS} as a function of time. This graph illustrates the time dependence of I_{DS} for a device according to FIG. 1 with a composition of PPy/Cl⁻(polypyrrole doped with Cl⁻) and a relatively rapid variation of V_{G}.

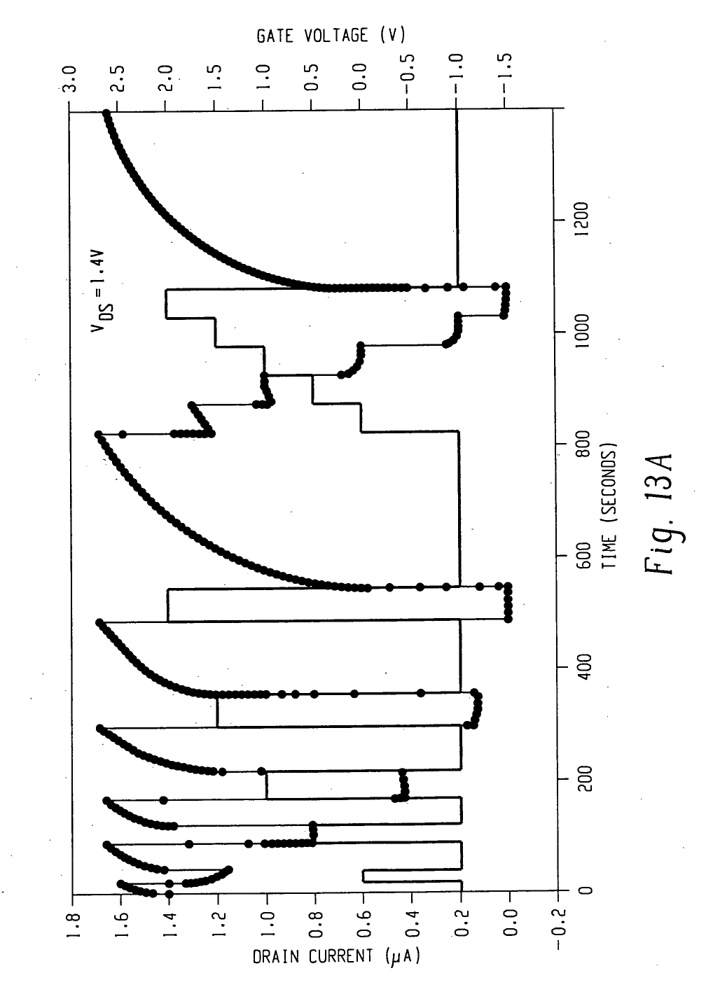

With reference to FIGS. 13A and 13B, illustrated is the relatively fast switching-off time of a device according to FIG. 1. The device switching-off time (T_{SW}) is less than 0.5 s and the on/off ratio is approximately 10³. FIG. 13B shows an expanded view of area (A) of FIG. 13A. This area quantifies the switch-off and switch-on times in sequence.

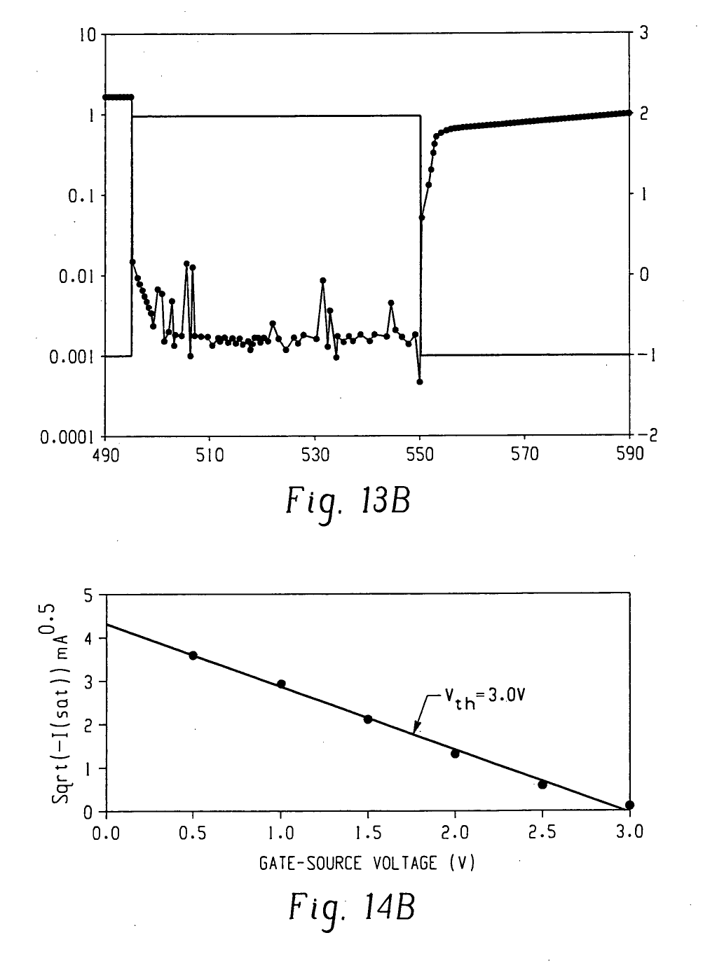

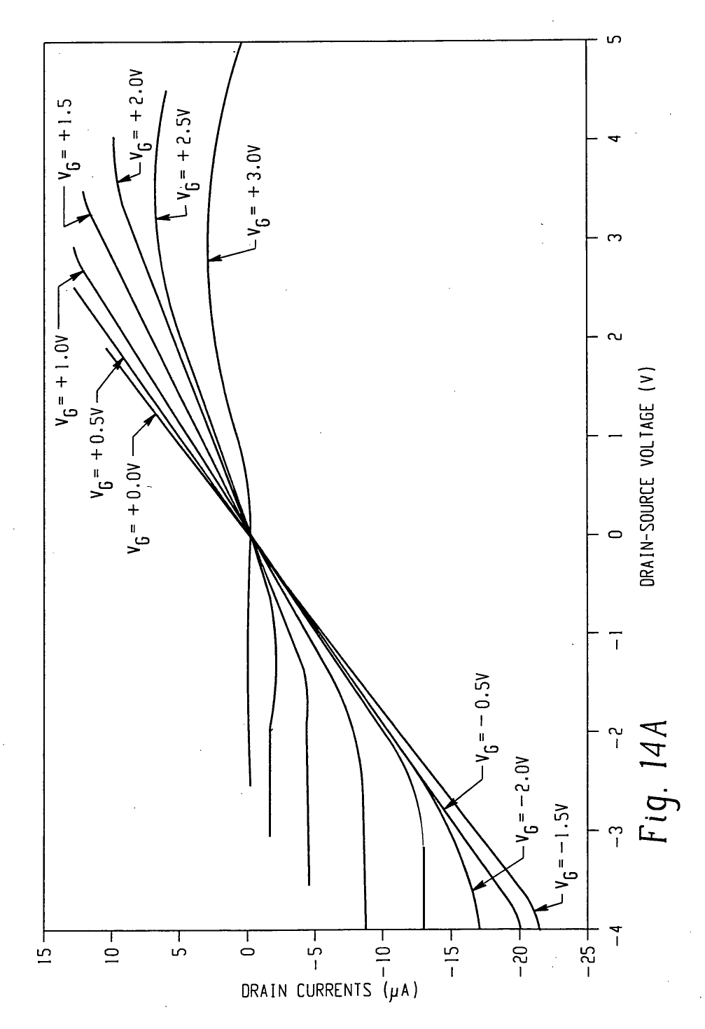

With reference to FIG. 14A, illustrated are drain current curves as a function of various gate voltages.

With reference to FIG. 14B, illustrated is a graph representing the saturation current as a function of the gate-source voltage. The threshold voltage Vₜₕ of the device equals 3.0 volts.

With reference to FIG. 15A, illustrated is an inverting amplifier configuration of a device according to FIG. 1. As illustrated in FIGS. 15B and 15C, this device provides an amplification of 2.1 for Vin@f=0.025 Hz and an amplification of 1.6 for Vin@f=0.11 Hz. As the frequency of the input voltage Vin is increased, wave distortion and lower amplifications result. The cutoff frequency of this device configuration is approximately 0.1 Hz.

With reference to FIG. 16A, illustrated is an inverting amplifier configuration of a device according to FIG. 1. As illustrated in FIGS. 16B and 16C, this device provides an amplification of 6.0 for Δ Vin=.5v@f=0.007 Hz and an amplification of 6.7 for Δ Vin 1.0v@f−0.007 Hz. Using this configuration, an amplification up to 20 can be achieved.

With reference to FIG. 17A, illustrated is a current source configuration of a device as illustrated in FIG. 1. FIG. 17B graphically illustrates the relationship of the drain current as a function of the drain-source voltage. The particular configuration and materials used here results in a constant current of 110 microamps for application of VDS exceeding 7 volts. Through control of the geometry of the active channel (including length, width and thickness of the conducting polymer between the source and the drain contacts) as well as the geometry of the gate electrode and the active channel, a wide range of constant currents varying over orders of magnitude are achieved. Similarly the specific geometry and composition of the device structure in FIG. 17A determines the threshold V_{DS} above which the I_{DS} is constant.

With reference to FIG. 18A, FIG. 18B and FIG. 18C, illustrated are the non-volatile RAM responses of a device as illustrated in FIG. 1. A non-volatile RAM function is achieved if V_{G}=V_{SD} of 0 V, where data storage times of hours is achieved. Note that in this example the V_{G} is the ‘write’ function writes or erases the information in this device. A positive V_{G} increases the resistance between source and drain. This increased resistance can remain for a long time of even days until a negative V_{G} is applied that resets the resistance to the lower value. The V_{SD} is the ‘read’ operation. The resulting I_{SD} is the signal ‘read’. The same device may be operated using a current source applied between the source and drain applying a known current, I_{SD}, as the ‘read’ operation. The memory signal ‘read’ is in this approach is the resulting V_{SD}. As illustrated in FIG. 18A, FIG. 18B and FIG. 18C, the device has a contrast between ‘1’ and ‘0’ state of 19%, 11% and 29%, respectively. Much larger contrasts can be achieved through choice of device geometry, choice of constituent polymers, and choice of V_{G} applied.

As described hereto, the above functions can be combined in a single multi-functional doped conducting polymer based field effect device, as illustrated in FIG. 1 and FIG. 5A and FIG. 5B. Additional functions include storing electrical charge and energy as a supercapacitor between the conducting polymer layer and the electrically conductive layer, these layers being separated by an insulating layer as illustrated in FIG. 1, FIG. 5A and FIG. 5B. The field effect device, as described, also functions as a sensor of organic, inorganic and biologic specifies. Application of multiple gate voltages to the field effect device described or electromagnetic radiation applied to the surface of the field effect device, as one or more gate voltages are applied, provides multi-functionality.

The exemplary embodiment has been described with reference to the preferred embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

1. A field effect device comprising:
an electrically conductive layer operative to provide a gate contact for the device;
a conducting polymer layer operative to provide source and drain contacts for the device, and an active layer; and
an insulating polymer layer formed between the electrically conductive layer and the conducting polymer layer,
wherein the layers in combination allow the device to be operative to perform at least two of a plurality of response functions, the plurality of response functions comprising:
varying reflectance and emissivity of electromagnetic radiation over a surface area by applying a voltage between the electrically conductive layer and the conducting polymer layer;
modulating electrical conductivity between the source contact and the drain contact by applying a second voltage between the conducting polymer layer and the electrically conductive layer;
amplifying low frequency electrical signals;
acting as a current source;
storing information in a non-volatile, re-writable form;
storing electrical charge and energy as a supercapacitor between the conducting polymer layer and the electrically conductive layer, separated by the insulating polymer layer; and
sensing the presence of organic, inorganic or biologic species.

2. The device according to claim 1, wherein the electrically conductive layer is a metal.

3. The device according to claim 1, wherein the electrically conductive layer is an electrically conducting polymer comprising a highly reflective surface.

4. The device according to claim 1, wherein the conducting polymer layer includes PEDOT:PSS.

5. The device according to claim 1, wherein the conducting polymer layer includes polythiophene, polypyrrole, polyaniline in the leucoemeraldine or pernigraniline form, sulfonated polyanilines and their derivatives, oligomers, copolymers, and blends, wherein the dopant for these conducting polymers is inorganic or organic species.

6. The device according to claim 5, wherein the said polyaniline is sulfonated in the range of 10% to 100% continuously.

7. The device according to claim 1, wherein the insulating polymer layer includes PVP.

8. The device according to claim 1, wherein the thickness of the conducting polymer layer is less than or equal to 10 microns.

9. The device according to claim 1, wherein the thickness of the conducting polymer layer is less than or equal to 400 nm.

10. The device according to claim 1, wherein the thickness of the insulating polymer layer is less than or equal to 10 microns.

11. The device according to claim 1, wherein the thickness of the insulating polymer layer is less than or equal to 400 nm.

12. The device according to claim 1, wherein the electrically conductive layer is less than 30 nm and provides partially transmissibility of electromagnetic radiation.

13. The device according to claim 1, further comprising:
a gate voltage source connected between the gate contact and the source contact,
wherein the gate voltage source controls the device to be operative to perform the said at least two of a plurality of functions.

14. The device according to claim 1, wherein the plurality of response functions comprises:
varying the reflectance and emissivity of electromagnetic radiation over a surface by applying a first voltage between the electrically conductive layer and the conducting polymer layer; and
modulating electrical conductivity between the source contact and the drain contact by applying the first or a second voltage between the conducting polymer layer and the electrically conductive layer.

15. A method of operating a field effect device comprising an electrically conductive layer operative to provide a gate contact for the device, the electrically conductive layer operative to provide a reflective surface; a conducting polymer layer operative to provide source and drain contacts for the device, and an active layer; and an insulating polymer layer formed between the electrically conductive layer and the conducting polymer layer, comprising the steps of:
combining the layers to allow the device to be operative to perform at least two of a plurality of response functions, the plurality of response functions comprising:
varying reflectance and emissivity of electromagnetic radiation over a surface area by applying a voltage between the electrically conductive layer and the conducting polymer layer;
modulating electrical conductivity between the source contact and the drain contact by applying a second voltage between the conducting polymer layer and the electrically conductive layer;
amplifying low frequency electrical signals;
acting as a current source;
storing information in a non-volatile, re-writable form;
storing electrical charge and energy as a supercapacitor between the conducting polymer layer and the electrically conductive layer, separated by the insulating polymer layer; and
sensing the presence of organic, inorganic or biologic species.

16. The method according to claim 15, further comprising the steps of:
connecting a gate voltage source between the gate contact and the source contact; and
controlling the gate voltage source to control the device to be operative to perform the said at least two of a plurality of functions.

17. The method according to claim 15, further comprising the steps of:
varying the reflectance and emissivity of electromagnetic radiation over a surface by applying a first voltage between the electrically conductive layer and the conducting polymer layer; and
modulating electrical conductivity between the source contact and the drain contact by applying the first voltage or a second voltage between the conducting polymer layer and the electrically conductive layer.

18. A field effect device comprising:
means for an electrically conductive layer to provide a gate contact for the device, and means for the electrically conductive layer to provide a reflective surface;
means for a conducting polymer layer to provide source and drain contacts for the device, and an active layer;
means for an insulating polymer layer formed between the electrically conductive layer and the conducting polymer layer; and
means for the layers in combination to allow the device to be operative to perform at least two of a plurality of response functions, the plurality of response functions comprising:
varying reflectance and emissivity of electromagnetic radiation over a surface area by applying a voltage between the electrically conductive layer and the conducting polymer layer;
modulating electrical conductivity between the source contact and the drain contact by applying a second voltage between the conducting polymer layer and the electrically conductive layer;
amplifying low frequency electrical signals;
acting as a current source;
storing information in a non-volatile, re-writable form;
storing electrical charge and energy as a supercapacitor between the conducting polymer layer and the electrically conductive layer, separated by the insulating polymer layer; and
sensing the presence of organic, inorganic or biologic species.

19. The device according to claim 18, further comprising:
means for connecting a gate voltage source between the gate contact and the source contact; and
means for controlling the gate voltage source to control the device to be operative to perform the said at least two of a plurality of functions.

20. The device according to claim 18, further comprising:
means for varying the reflectance and emissivity of electromagnetic radiation over a surface by applying a first voltage between the electrically conductive layer and the conducting polymer layer; and
means for modulating electrical conductivity between the source contact and the drain contact by applying the first voltage or a second voltage between the conducting polymer layer and the electrically conductive layer.
